(19) United States
(12) Patent Application Publication
(10) Pub. No.: US 2008/0230722 A1
(43) Pub. Date: Sep. 25, 2008

(54) INTEGRATED CIRCUIT AND METHOD INCLUDING A PATTERNING METHOD

(75) Inventor: Klaus Elian, Alteglofsheim (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: Qimonda AG, Muenchen (DE)

(21) Appl. No.: 11/937,719

(22) Filed: Nov. 9, 2007

(30) Foreign Application Priority Data
Nov. 10, 2006 (DE) 10 2006 053 074.8

(51) Int. Cl. G21K 5/00; G03F 7/20

(52) U.S. Cl. 250/492.2; 430/296

(57) ABSTRACT

A method of making an integrated circuit including a patterning method using chemically amplified photoresists and exposure apparatus is disclosed. One embodiment provides a photoresist layer exposed using a screened particle beam or a projection exposure with a projection wavelength of less than a limit wavelength below which secondary electrons are initiated by the exposure in the photoresist layer. The photoresist layer is irradiated, at least in a section subjected to the exposing, with UV light having a spectrum below a limit frequency corresponding to the limit wavelength.

### CROSS-REFERENCE TO RELATED APPLICATIONS

This Utility Patent Application claims priority to German Patent Application No. DE 10 2006 053 074.8 filed on Nov. 10, 2006, which is incorporated herein by reference.

### BACKGROUND

One embodiment relates to a method of making an integrated circuit including a patterning method. Further embodiments relate to an apparatus an exposure apparatus which enables such a patterning method.

In semiconductor process technology, patterning exposure methods are used both in the production and patterning of semiconductor wafers and in the production of masks for further patterning exposure methods for semiconductor wafers. The bare mask and the semiconductor wafer are coated with a uniform thin layer of a radiation-sensitive polymer film. The polymer film is patterned by using an electron or ion beam, by using ultraviolet light having a wavelength of 257, 248, 193 or 157 nm or extreme UV radiation (EUV) having a wavelength of 13.5 nm. Irrespective of the type of radiation source, the radiation- sensitive polymer layer is usually referred to as a photoresist. In the exposed sections, the radiation initiates a chemical reaction in the film layer which alters the solubility of the exposed sections relative to that in the unexposed sections.

Chemically amplified photoresists are used both for EUV lithography and for particle beam lithography, these photoresists enabling a comparatively high resolution in conjunction with comparatively high sensitivity. Such photoresists are based on a catalytic mechanism which involves a catalyst, usually a photo acid, being released by the action of a comparatively low dose of the exposure radiation.

In electron beam lithography, for instance, the catalytic reaction is in this case not initiated by the comparatively small number of primary electrons of the electron beam, but rather predominantly by the secondary electrons generated by the primary electrons. The secondary electrons cleave a photo acid precursor in the photoresist (PAG, photo acid generator) and generate the acid required for patterning.

The limits of the use of chemically amplified photoresists are described for instance in “Report on EUV resist process limitations”; van Steenwickel et al.; Philips Research Eindhoven; technical note PR-TN 2005/00570. Accordingly, when using chemically amplified photoresists, exposure dose, resolution and edge roughness cannot be optimized independently of one another. Accordingly, the exposure dose and thus the diffusion distance of the photochemically formed acids are usually reduced nowadays in order to improve the resolution, a significantly reduced throughput being accepted on the respective exposure apparatus.

An EUV exposure method in which, in order to improve the exposure effectiveness, part of an exposing EUV radiation is reflected back into the photoresist layer in part as long-wave DUV radiation from a specially formed hard mask underlying the photoresist layer is described in U.S. Pat. No. 7,033,739 B2.

For these and other reasons, there is a need for the present invention.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates a schematic illustration of an EUV projection exposure apparatus with additional UV flood exposure according to one embodiment of making an integrated circuit.

FIG. 2 illustrates a schematic illustration of an electron beam exposure apparatus with flood exposure according to another embodiment.

FIG. 3 illustrates a schematic illustration of an electron beam exposure apparatus with additional focused UV irradiation according to a further embodiment.

FIG. 4 illustrates a simplified flowchart of a patterning method according to a further embodiment.

FIG. 5 illustrates an emission spectrum of a UV source for use in an exposure apparatus according to the invention according to a further embodiment.

FIG. 6 illustrates absorption spectra of a chemically amplified photoresist for elucidating the background.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

One or more embodiments provide a method of making an integrated circuit including a patterning method, and also a system configured to perform the method. In one embodiment, the method is a semiconductor process, used for making semiconductor wafers.

In accordance with a patterning method according to one embodiment, a photoresist layer is firstly applied on the substrate. The substrate is, for instance, a bare mask for a projection exposure method or a semiconductor substrate, for example a silicon wafer. The photoresist layer is subjected to patterning exposure. The patterning exposure is effected either by using a screened particle beam or a projection exposure with a projection wavelength that is less than a limit wavelength below which secondary electrons are initiated in the photoresist by the projection exposure. The patterning exposure is accordingly an electron beam, an ion beam or a short-wave UV exposure, for instance an EUV exposure.

Simultaneously with the patterning exposure, the photoresist layer is subjected to a comparatively long-wave UV additional irradiation, the minimum wavelength of which is greater than the limit wavelength. As a result of the excitation with the longer-wave UV light, low-energy secondary electrons initially absorb from the additional UV irradiation enough additional energy to initiate the PAG cleavage. For the same exposure dose or duration of the patterning exposure, the number of those secondary electrons which have the energy required for the catalytic reaction (PAG cleavage) and release photo acid is increased. Consequently, it may be possible for instance to reduce the exposure dose or duration of the patterning exposure, whether it is a screened particle beam or an EUV projection exposure.

After the patterning exposure, the photoresist is developed, a photomask emerging from the photoresist layer. The substrate is patterned using the photomask, wherein the photomask can function as an etching or implantation mask, for example.

The minimum wavelength of the additional irradiation is coordinated for instance with the properties of the photoresist in such a way that the photoresist is insensitive toward the additional irradiation alone, such that, in an advantageous manner, the resolution of the exposure method is determined solely by the secondary electron effect. Above and hereinafter the additional “exposure” of the photoresist layer with comparatively long-wave UV light is referred to as “irradiation”, while the term “exposure” is intended to be reserved for the operation which initiates the exposure reaction in the photoresist. The additional irradiation alone does not initiate an exposure reaction in the photoresist.

The additional irradiation of the photoresist layer is effected for instance using UV light having a spectrum below a limit frequency corresponding to a minimum wavelength of 250 nm. The wavelength of the projection exposure must be short enough to initiate secondary electrons, and is for instance less than 100 nm and in one embodiment 13.5 nm. In accordance with one embodiment, the photoresist layer comprises a chemically amplified photoresist, for instance one which is chemically altered in the exposed sections by secondary electrons initiated by the particle beam or the projection exposure.

In accordance with one embodiment, the photoresist used is one which contains a catalyst precursor (e.g., PAG, photo acid generator), from which a catalytically acting substance emerges through the action of the secondary electrons. According to a further embodiment, the additional irradiation is embodied as flood irradiation. In this case, the patterning exposure can be a particle beam imaging method or a projection exposure method.

According to another embodiment, the patterning exposure is a particle beam imaging method, while the UV irradiation is provided as irradiation focused on the photoresist layer around the particle beam. Since UV light, in the case of chemically amplified photoresists, can lead to reactions in the photoresist even after the exposure, the exposure process is advantageously largely decoupled from the subsequent development process by using the focused UV irradiation. The UV excitation of the low-energy electrons in the photoresist extends the spatial region in which secondary electrons are available with enough energy for initiating the catalytic reaction. If the exposure dose of the patterning exposure is not reduced, this leads to a local reduction of the resolution.

In accordance with another embodiment, which likewise relates to a particle beam imaging method as patterning exposure, in which the structures are written successively and in which information about the type of structure to be written is basically available to a control of the imaging method, the intensity of the UV irradiation is controlled depending on the structure size of the structure to be written in each case. By way of example, the UV irradiation is reduced or turned off when writing finely patterned sections and is turned on or increased in intensity when imaging coarsely patterned sections.

The patterning exposure method is for instance an electron beam imaging method or an EUV projection exposure method, for which tried and tested chemically amplified photoresists are advantageously available.

A further embodiment provides a first exposure apparatus. The first exposure apparatus comprises a particle source emitting a particle beam, and a focusing unit, which focuses the particle beam. The first exposure apparatus furthermore comprises a receiving unit, which receives a substrate and aligns it with respect to the focusing unit, and a control unit, which controls the particle beam and/or the spatial coordinates of the receiving unit depending on image data.

The exposure apparatus furthermore comprises a UV irradiation unit, which irradiates at least one section of a substrate arranged in the receiving unit with UV light having a spectrum below a limit frequency corresponding to a minimum wavelength of 248 nm. The substrate is for example an EUV bare mask or a semiconductor substrate, for instance a silicon wafer. The exposure apparatus may enable an increased throughput by reduction of the exposure duration. During the writing of EUV bare masks, damage in the layer system of the bare mask may be avoided by reduction of the exposure dose.

According to a further embodiment, the UV irradiation unit flood-“exposes” the substrate arranged in the receiving unit. This may result in a simple construction of the exposure apparatus.

According to a further embodiment, the intensity of the UV light can be controlled by the control unit of the exposure apparatus depending on the image data to be imaged in each case. The UV irradiation unit can be turned on and off for instance by the control unit depending on the image data. It is thus possible for example for those image data which are assigned to finely patterned sections to be written at high resolution, and for those image data which are assigned to coarsely patterned sections to be written at high speed.

The spectrum of the UV light lies for instance above a wavelength of 280 nm, that is to say below a limit frequency corresponding to a wavelength of 280 nm, such that no exposure reaction is initiated in customary chemically amplified photoresists by the UV irradiation alone. A plurality of known photoresists may therefore be used.

Another exposure apparatus comprises a UV radiation source emitting UV light having a projection wavelength of less than 100 nm, preferably 13.5 nm. The exposure apparatus furthermore comprises a focusing unit, which focuses the UV radiation, and a mask arranged in the beam path of the focused UV light and having sections opaque and transparent with respect to the UV light, and also a receiving unit, which can receive a substrate and align it with respect to the beam path.

The exposure apparatus may furthermore comprise a UV irradiation unit, which can irradiate at least one section of a substrate arranged in the receiving unit with UV light having a spectrum below a limit frequency corresponding to a wavelength of 250 nm. Such an exposure apparatus enables the exposure of the substrate with a reduced exposure duration, such that the throughput may be increased on this exposure apparatus.

In accordance with one embodiment of the exposure apparatus, the UV irradiation unit flood-“exposes” the substrate arranged in the receiving unit, such that a very simple construction of the exposure apparatus results. The UV irradiation unit emits for instance UV light having a spectrum below a limit frequency corresponding to a wavelength of 280 nm. This may make it possible to use a large group of chemically amplified photoresists which are generally not exposed by a UV irradiation with a wavelength of greater than 280 nm, or in which no exposure reaction is instigated by such an irradiation.

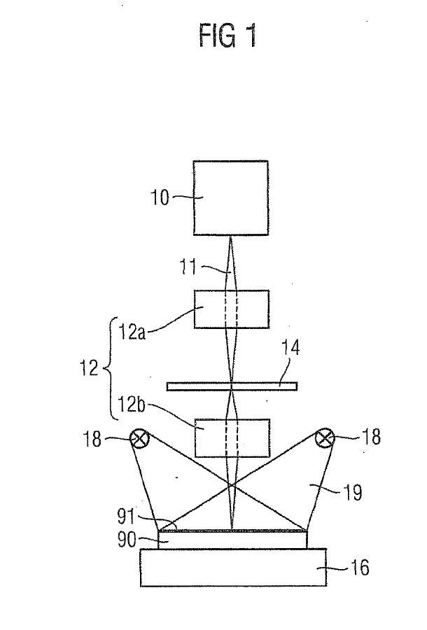

FIG. 1 is the schematic illustration of an EUV projection exposure apparatus according to one embodiment. A radiation source 10 emits an EUV beam 11 having a wavelength of 13.5 nm. The EUV beam 11 is focused by the first part 12a of a focusing unit 12 onto a mask 14 and by a second part 12b of the focusing unit 12 onto a photoresist layer 91 covering a substrate 90. The substrate 90 is a bare mask or a semiconductor substrate, for instance a silicon wafer. The substrate 90 lies on a receiving unit 16 of the exposure apparatus. The mask 14 has a structure having sections opaque and transparent with respect to the EUV beam 11. The structure of the mask 14 is transferred into the photoresist layer 91 by using the EUV beam 11. The photoresist layer 91 comprises a chemically amplified photoresist. Secondary electrons are initiated in the sections exposed by the EUV beam 11. If the secondary electrons attain a minimum energy, then a catalytic reaction is initiated in the exposed sections of the photoresist layer 91. As a consequence of said reaction, photo acid is generated, which alters the solubility properties of the photoresist layer 91 in the exposed sections, while the solubility properties of the unexposed sections of the photoresist layer 91 remain unchanged.

In addition, the EUV projection exposure apparatus comprises a UV irradiation unit 18 emitting UV light 19 having such frequencies which are unable to initiate secondary electrons in the photoresist layer 91. By way of example, the UV irradiation unit 18 emits UV light 19 having a frequency spectrum below a limit frequency corresponding to a wavelength of 257 nm or 280 nm.

Such secondary electrons in the photoresist layer 91 which are initiated by the EUV beam 11 and the energy of which initially does not suffice to instigate the catalytic reaction absorb the requisite remaining energy from the UV radiation 19 emitted by the UV irradiation unit 18. The effectiveness of the exposure is increased.

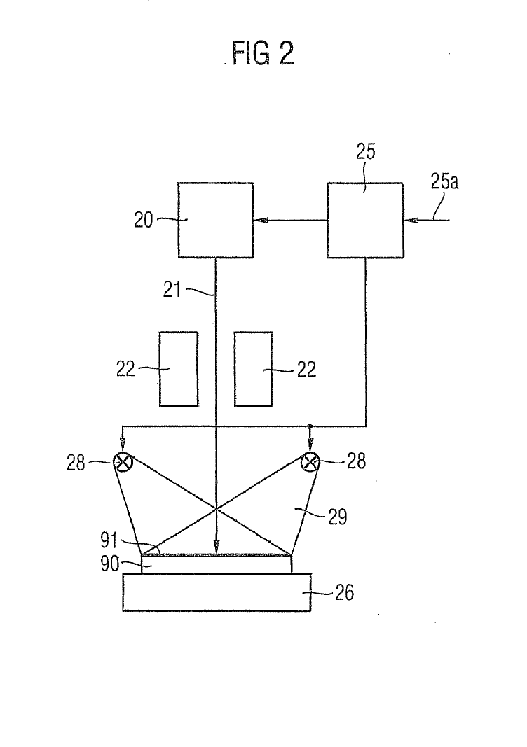

FIG. 2 illustrates an electron beam exposure apparatus according to a further exemplary embodiment. An electron source 20 emits an electron beam column 21, which, focused by using electric and magnetic fields of a focusing unit 22, impinges on a photoresist layer 91 covering a substrate 90. The substrate 90, for instance an EUV bare mask, lies on a receiving unit 26 of the exposure apparatus. The electron source 20 and thus the electron beam column 21 are controlled by a control unit 25 depending on image data 25a. The electron beam column 21 is guided over the photoresist layer 91 for instance by moving the receiving unit 26 relative to the electron beam column 21 and in the process is turned on and off depending on the image data 25a for the patterning exposure. The primary electrons incident via the electron beam column 21 initiate secondary electrons in the photoresist layer 91, said secondary electrons having only in part the energy required for instigating the catalytic reaction. A UV irradiation unit 28 flood-“exposes” the photoresist layer 91 with comparatively long-wave UV light 29, such that initially low-energy secondary electrons can absorb from the UV irradiation 29 enough energy to obtain the energy required for instigating the catalytic reaction. Since the initially lower-energy secondary electrons occur at a larger distance with respect to the impinging primary electron beam, the resolution of the projection method may be slightly reduced, under certain circumstances.

The reduction of the resolution can be prevented by the UV irradiation unit 28 being turned on and off or regulated in terms of the intensity by the control unit 25 depending on the image data 25a. The control unit 25 can accordingly evaluate the image data 25a as to whether at the moment fine or coarse structures, pixels at a large distance from a structure edge or pixels along a structure edge are being written, and control the UV irradiation unit 28 depending on this information. Such an exposure apparatus enables both a high resolution in finely patterned regions and, due to the reduced exposure duration in the coarsely patterned regions, an increased throughput.

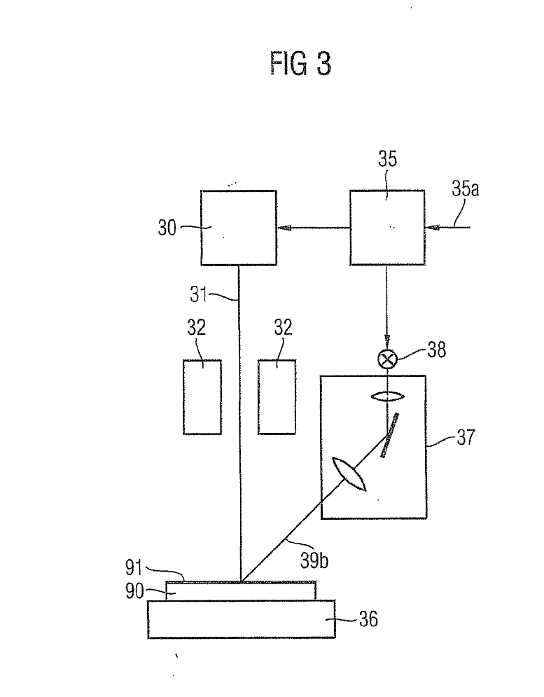

A long-wave UV exposure can initiate subsequent reactions, under certain circumstances, in already exposed sections. The electron beam exposure apparatus with additional long-wave UV irradiation as illustrated in FIG. 3 therefore provides a UV focusing unit, by using which only the respectively exposed section of the photoresist layer 91 is additionally irradiated with long-wave UV light.

An electron source 30 emits an electron beam column 31, which, focused by the focusing unit 32, impinges on the photoresist layer 91 covering the substrate 90. The substrate 90, for instance an EUV bare mask, lies on a receiving unit 36. The light from a UV irradiation unit 38 is focused by a UV focusing unit 37 and controlled in such a way that focused long-wave UV light 39b impinges on the photoresist layer 91 only where the electron beam column 31 is actually impinging. A control unit 35 controls the electron source 30 depending on the image data 35a and additionally regulates the UV irradiation unit 38 downward and upward, or turns it off and on.

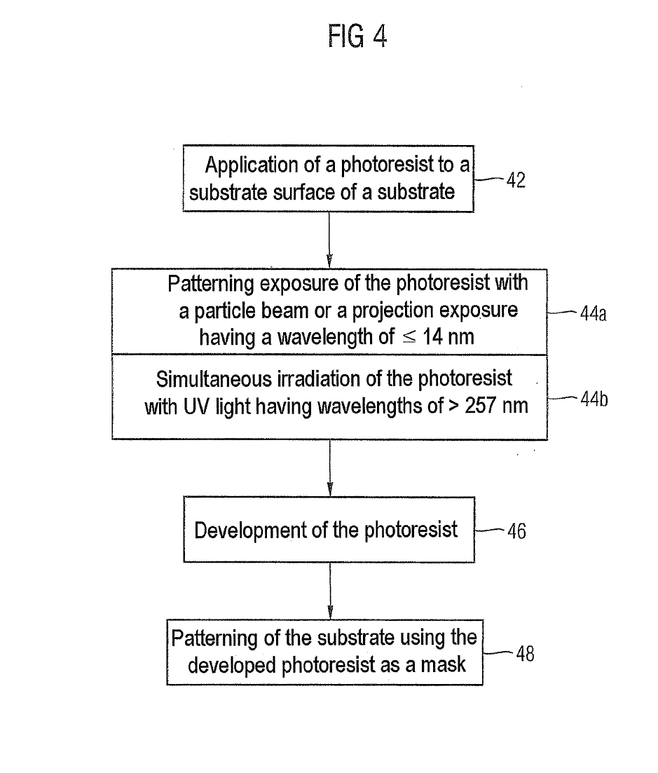

FIG. 4 illustrates a schematic flowchart. In accordance with process 42, a chemically amplified photoresist is applied to a substrate surface of a substrate. In accordance with process 44a, the photoresist is subjected to a patterning exposure. In this case, the patterning exposure is a screened particle beam or a projection exposure having a wavelength of 193 nm, 157 nm, 13.5 nm or less. In accordance with process 44b, simultaneously with the patterning exposure, the photoresist is subjected to an additional UV irradiation with an emission spectrum below a limit frequency corresponding to a wavelength of 257 nm.

In accordance with process 46, the photoresist is developed and subsequently, in accordance with process 48, the substrate is patterned using the developed photoresist as a mask.

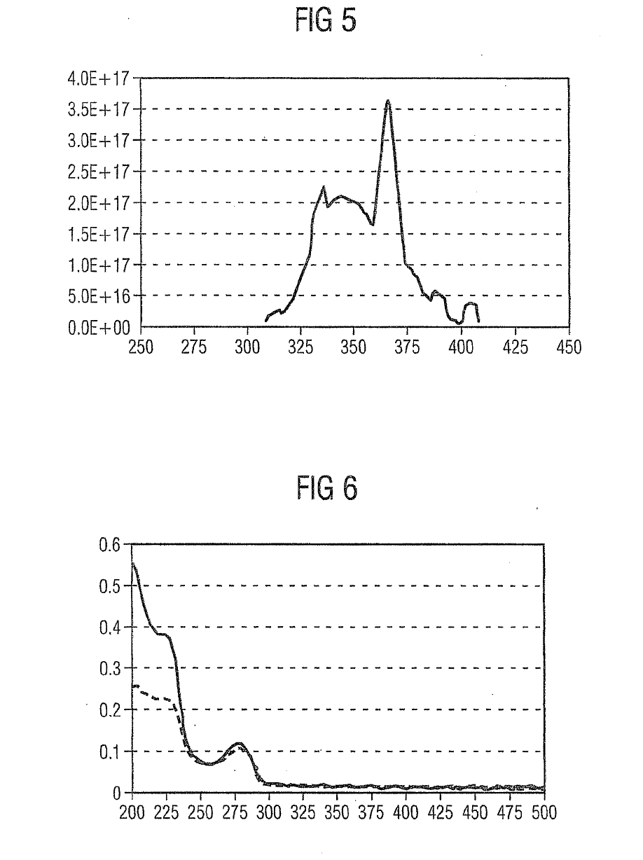

FIG. 5 illustrates the emission spectrum of a UV irradiation unit suitable for use in one of the embodiments of the exposure apparatus. The UV exposure unit emits UV light having wavelengths of between 305 and 410 nm with a maximum at a wavelength of approximately 370 nm.

FIG. 6 illustrates the absorption spectra of a chemically amplified photoresist. Neither the exposed (lower curve) nor the unexposed (upper curve) photoresist absorbs at wavelengths of greater than 300 nm.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of making an integrated circuit including patterning a layer comprising:
applying a photoresist layer to a substrate;
exposing the photoresist layer via a screened particle beam or a projection exposure with a projection wavelength of less than a limit wavelength below which secondary electrons are initiated by the exposure in the photoresist layer; and
irradiating, simultaneously with respect to the exposing, the photoresist layer, at least in a section subjected to the exposing, with UV light having a spectrum below a limit frequency corresponding to the limit wavelength.

2. The method of claim 1, further comprising:
developing the photoresist layer after exposing the photoresist layer to form a photomask from the photoresist layer; and
patterning the substrate using the photomask.

3. The method of claim 1, comprising coordinating the spectrum of the UV light and a photoresist forming the photoresist layer with one another in such a way that no exposure reaction is initiated in the event of an irradiation solely with the UV light in the photoresist.

4. The method of claim 1, comprising irradiating the photoresist layer with UV light having a spectrum above a minimum wavelength of 257 nanometers.

5. The method of claim 4, comprising exposing the photoresist layer with a projection exposure whose projection wavelength is at most 100 nm.

6. The method of claim 1, comprising providing the photoresist layer from a chemically amplified photoresist.

7. The method of claim 1, comprising providing the photoresist layer from such a photoresist which contains a catalyst precursor from which a catalytically acting substance emerges through the action of the secondary electrons.

8. The method of claim 1, comprising embodying the UV irradiation as flood irradiation.

9. The method of claim 1, comprising:
exposing the photoresist using a particle beam imaging method; and
embodying the UV irradiation as irradiation focused on the photoresist layer around the particle beam.

10. The method of claim 1, comprising:
exposing the photoresist using a particle beam imaging method; and
controlling the intensity of the UV irradiation depending on the structure size of the structure to be written in each case.

11. The method of claim 1, comprising exposing the photoresist using a particle beam imaging method; and
turning off the UV irradiation for imaging fine structures and is turned on for imaging coarse structures.

12. The method of claim 1, comprising exposing the photoresist using an EUV projection exposure method.

13. An apparatus for making an integrated circuit including an exposure apparatus comprising:
a particle source capable of emitting a particle beam;
a focusing unit, which is configured to focus the particle beam;
a receiving unit, which is configured to receive a substrate and to align it with respect to the focusing unit;
a control unit, which is configured to control the particle beam and the receiving unit depending on image data; and
a UV irradiation unit, which is capable of irradiating at least one section of a substrate arranged in the receiving unit with UV light having a spectrum above a minimum wavelength of 257 nm.

14. The apparatus of claim 13, comprising wherein the UV irradiation unit is capable of flood-irradiating the substrate arranged in the receiving unit.

15. The apparatus of claim 13, comprising wherein the control unit is configured to control the intensity of the UV light depending on the image data to be imaged in each case.

16. The apparatus of claim 13, comprising wherein the control unit is configured to turn the UV irradiation unit on and off depending on the image data.

17. The apparatus of claim 13, comprising wherein the minimum wavelength of the UV light is 280 nanometers.

18. The apparatus of claim 13, further comprising:
a UV focusing unit, which is configured to focus the UV light emitted by the UV irradiation unit and to form a UV beam focused on the substrate around the particle beam.

19. An exposure apparatus comprising:
a UV radiation source capable of emitting UV radiation having a projection wavelength of less than a limit wavelength below which secondary electrons are initiated by the exposure in the photoresist layer;
a focusing unit configured to focus the UV radiation;
a mask arranged in the beam path of the focused radiation and having sections opaque and transparent with respect to the UV radiation;
a receiving unit configured to receive a substrate and to align it with respect to the beam path; and
a UV irradiation unit capable of irradiating at least one section of a substrate arranged in the receiving unit with UV light having a spectrum above a minimum wavelength of 257 nm.

20. The exposure apparatus of claim 19, comprising wherein the UV irradiation unit is capable of flood-irradiating the substrate arranged in the receiving unit.

21. The exposure apparatus of claim 19, comprising wherein the minimum wavelength of the UV light is 280 nanometers.
